(19) United States
(12) Patent Application Publication
(10) Pub. No.: US 2015/0129189 A1
(43) Pub. Date: May 14, 2015

(54) Method and Apparatus for Reducing the Mechanical Stress when Mounting Assemblies with Thermal Pads

(71) Applicant: Yao Hua Wang, Adelaide (AU)

(72) Inventor: Yao Hua Wang, Adelaide (AU)

(73) Assignee: NOKIA SOLUTIONS AND NETWORKS OY, Espoo (FI)

(21) Appl. No.: 14/377,701

(22) PCT Filed: Feb. 9, 2012
(86) PCT No.: PCT/CN2012/070974

§ 371 Date: Jan. 20, 2015

(51) Int. Cl. F28F 3/00; H05K 13/04

(52) U.S. Cl. CPC F28F 3/00; H05K 13/04
USPC 165/185; 29/428

(57) ABSTRACT

It is provided a device and method for mounting of a heat sink on a printed circuit board with one or more electronic components to be cooled reducing the mechanical stress on the electronic components and the printed circuit board. The thermal contact between the heat sink and the electronic components to be cooled is formed by a thermal pad. The surface of the heat sink which is in contact with the thermal pad has at least one cavity into which the thermal pad can spread when the electronic component and the heat sink are pressed against each other thereby compressing the thermal pad.

### TECHNICAL FIELD

Embodiments of the present invention relate generally to the mounting of electronic equipment and more particularly to the mounting of heat sinks. The invention relates to a heat sink and a method for mounting of a heat sink on a printed circuit board with one or more electronic components to be cooled reducing the mechanical stress on the electronic components and the printed circuit board.

### BACKGROUND

During operation electronic components like a CPU or another chip generate heat which must be reliably dissipated in order to avoid overheating of the components, which could damage them. Heat sinks, usually made from aluminum or copper, can absorb the heat generated by the electronic components and dissipate it to the environment. The heat transfer from the heat generating electronic component to the heat dissipating heat sink however is obstructed by microscopic air gaps present due to the imperfectly flat and smooth surfaces of the components. One common means to improve the heat transfer is to apply thermal grease between the electronic component and the heat sink, which increases the thermal conductivity of a thermal interface by filling the microscopic air gaps.

As an alternative to thermal grease often thermal gap pads are placed between the electronic component and the heat sink, because they are cleaner and generally easier to install. Thermal pads usually are a pre-formed square or rectangle of solid material, often paraffin based. They are commonly found on the underside of heat sinks to aid the conduction of heat away from the component being cooled into the heat sink.

During the assembly of the system consisting of the one or more electronic components and the heat sink compressive forces are applied to the thermal pad by e.g. screws or clamps. These compressive forces cause a deflection of the pad as the distance between the components decreases. This induces the thermal pad to effectively fill both micro and macro voids between the components and the heat sink, which in turn maximizes the rate of thermal transfer through the system. The pads are highly flexible, but nevertheless this deflection also causes stress due to inherent resistance of the pads to deflection. This stress can damage delicate components of the assembly, but may also cause many kinds of failures in printed circuit boards such as solder points crack, printed circuit board deformation and others.

In the article “Stress Minimization During Deflection of Thermally Conductive Gap Pads”, published in the 2007 Proceedings of the Twenty third IEEE Semiconductor Thermal Measurement and Management Symposium Karen Bruzda investigates ways to control and reduce this stress and shows that the vast majority of the observed stress reduction is due to lateral pad motion and therefore it is important not to impede this motion, i.e. the pad material must have the possibility to escape the compressive forces to the side.

The pad material may have the possibility to escape towards the outer edge of the pad, but it may also have the possibility to escape towards holes punched or cut into the pad. Correspondingly in the prior art slots have been cut into the thermal pad. This way the pad material did have the possibility to escape outside, i.e. towards the border of the pad, but in addition also towards inside the new slot by partially filling the slot which has been cut out before. In a simpler implementation only slits have been cut into the pad, which also reduced the stress.

Further investigations have shown that the observed stress reduction is the greater the longer the contour of the outer edge of the pad or of the hole cut into the pad is. So as a consequence a hole cut into the pad for reducing the stress caused by the assembly of the heat generating electronic element and the heat sink with the thermal pad in between should not be just circular or quadratic—better are narrow and long structures, e.g. strip-shaped holes.

Cutting material out of the thermal pad, especially in the form of long, narrow stripes, fulfills well its purpose to reduce the stress caused by the assembly of the heat generating electronic element and the heat sink with the thermal pad in between, but this method has two considerable flaws:
The cutting makes the thermal pad very soft and flexible, so it is very often deformed before it can be attached to the heat sink.
Because the thermal pad is very soft, only simple shapes of cutting can be applied. This limits the release of press which can be achieved this way.

The object of the present invention is to overcome the flaws of the state of the art mentioned above. In particular the invention aims to have a good mechanical stability of the thermal pad while still achieving a stress reduction.

### SUMMARY

In order to allow a lateral pad motion under the pressure exercised to one side of the thermal pad by the electronic component to be cooled and to the other side of the thermal pad by the heat sink, when both are assembled together, some free volume may be offered to the thermal pad where it can move into. The free volume may be a slot in the thermal pad, as seen in the prior art. The known disadvantage is the more delicate handling of the thermal pad when a slot has been cut into it.

The present invention allows an easier handling of the thermal pad by leaving the thermal pad itself uncut and by offering a free volume in the surface of the heat sink where the pad material may spread into. This may be a cavity in the surface of the heat sink. This cavity allows the thermal pad material to escape the pressure to the side by spreading into the free volume offered by the cavity in the heat sink. The cavity may have some basic geometric shape such as a polygon, an ellipsoid, an oval or any other geometric shape.

As has been shown above a long contour of a slot cut into the thermal pad could have an outstanding potential to reduce the stress induced by mounting a heat sink on an electronic element with a thermal pad in between. However long contours are nearly impossible to be cut into the soft thermal pad. According to the present invention a cavity buried into the heat sink can be shaped in the desired form. A well suited form for a cavity applied to the surface of the heat sink may be the form of a groove. There may be one groove or an array of grooves on the surface of the heat sink. The groove may have a basic geometric shape. There may also be one or more grooves in the form of a meander filling the surface of the heat sink which is to be covered by the thermal pad. The pattern of a meander may be known from rivers where a slowly creeping river meanders back and forth across its down-valley axis.

### BRIEF DESCRIPTION OF THE DRAWINGS

FIG. 1 shows the typical assembly in which a thermal pad is applied.

FIG. 2 shows several thermal pads of the prior art, from which material is cut out or into which slits are cut.

FIG. 3 shows in an exemplary embodiment of the invention the side of a heat sink which in an assembly is directed towards the electronic component to be cooled.

### DETAILED DESCRIPTION OF THE INVENTION

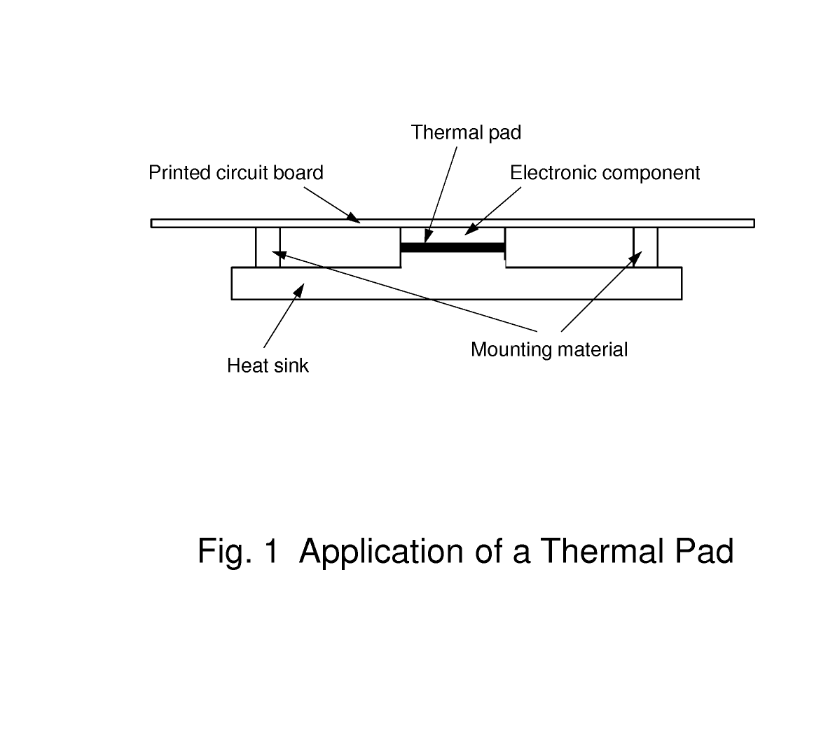

In FIG. 1 the typical configuration of a printed circuit board with one or more electronic components to be cooled, a heat sink to be fixed on the printed circuit board and a thermal pad between the heat sink and one of the electronic components to be cooled is shown. The surface of the one or more components to be cooled and the heat sink are facing each other. Between the component and the heat sink the thermal pad is placed. The heat sink may have one or more projecting structures which may compensate a different height of the components, so that all components to be cooled by the heat sink may have the same gap with the opposite heat sink surface. A heat sink with such projecting structures may be produced e.g. by die casting technique. The heat sink may be fixed on the printed circuit board by means of a suited clamping system or any other holding devices.

In particular if more than one electronic component is to be cooled by the heat sink, the adjustment of the distance between the printed circuit board and the heat sink may become critical: If the distance between the printed circuit board and the heat sink is too great, the pressure on the thermal pad may be too low, and the heat transfer to the heat sink may collapse due to a bad or missing contact of the thermal pad with the heat sink and the electronic component to be cooled. On the other hand, if the distance between the printed circuit board and the heat sink is too small, the pressure between the printed circuit board and the heat sink may be too high, and the electronic component to be cooled may be damaged, but also many kinds of failures in the printed circuit board such as solder points crack, printed circuit board deformation and others may happen. This is especially critical if more than one component at a time has to be adjusted for a good thermal contact with the heat sink.

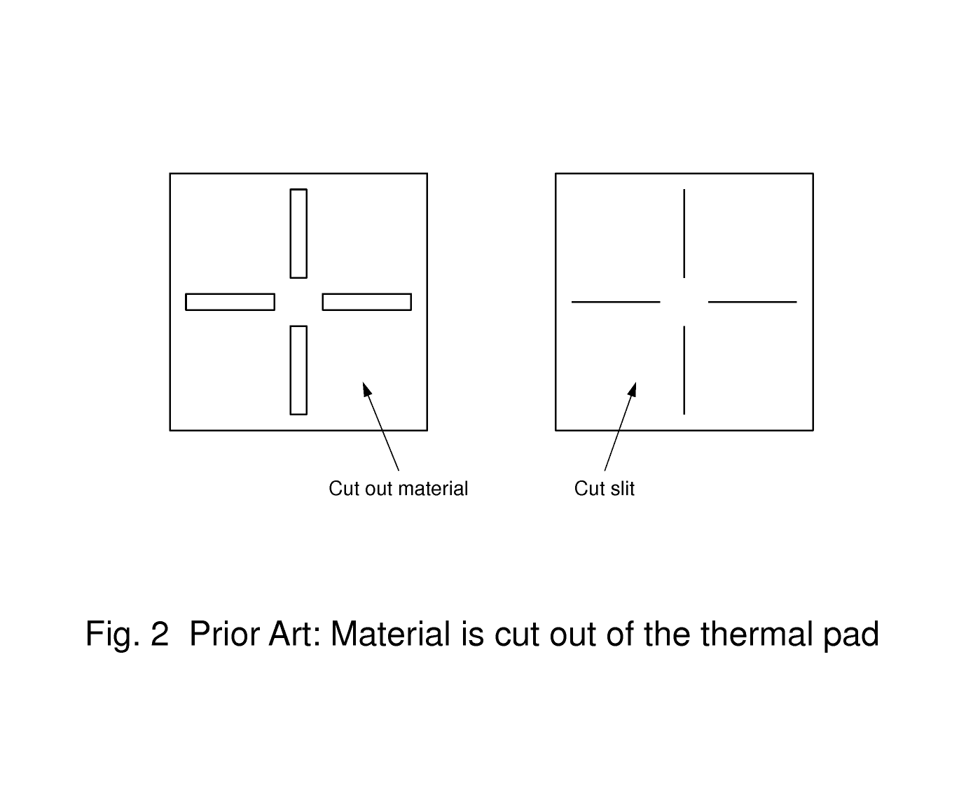

FIG. 2 shows thermal pads where the stress exercised by the thermal pad is reduced by prior art technique: In order to create free space in the thermal pad where excess material may spread when pressure is applied on the thermal pad, slots are cut out of the thermal pad. Shown are here four rectangular slots arranged to form a cross, but there are many other shapes possible which may be used as well. Even simple slits in the thermal pad have been found to be helpful in reducing the stress exercised on the component on the printed circuit board.

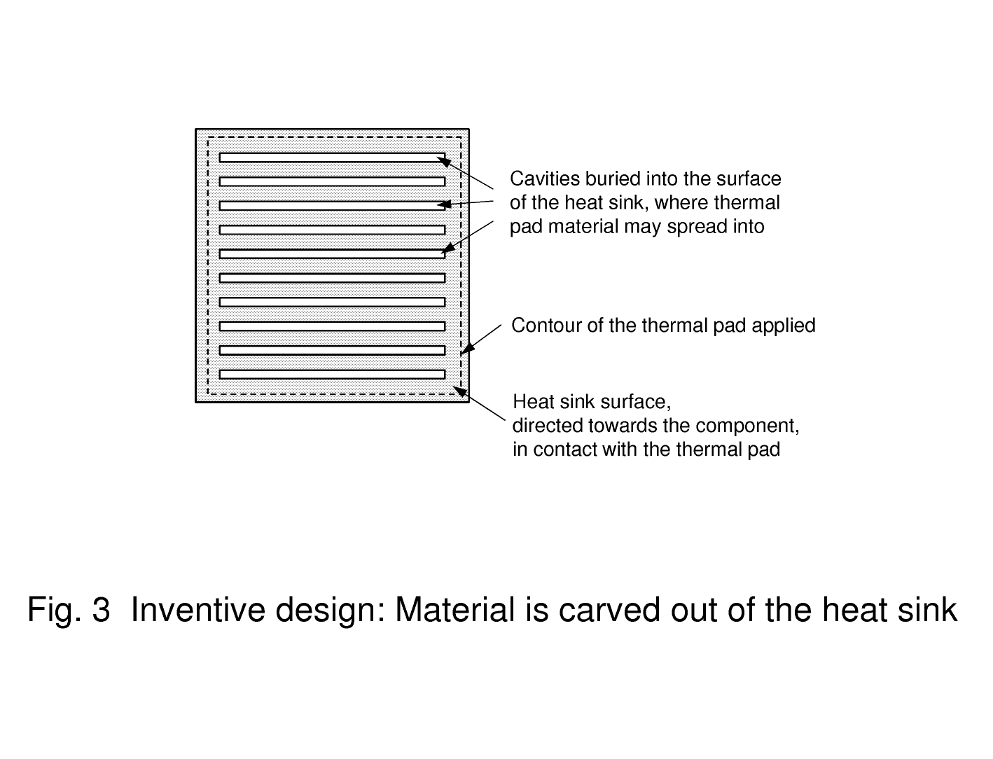

FIG. 3 shows an exemplary embodiment of the invention: Shown is the surface of the heat sink as it is opposed to the upper side of the electronic component. Cavities are buried in this surface into which thermal pad material may spread when pressure is exercised on the thermal pad by the electronic component to be cooled on one side and by the heat sink on the other side.

As mentioned above the contour of the one or more cavities should be preferably long. So an advantageous shape of such a cavity may be the shape of a groove. FIG. 3 shows the surface of the heat sink filled by an array of grooves which is intended to be covered by a thermal pad. The dotted lines indicate the contour of the thermal pad which is to be applied on the heat sink.

Another advantage of the invention is, that the claimed heat sink including the projecting structures mentioned above and including the cavities buried into the heat sink may be formed in one step by die casting. In another way of manufacturing the cavities may be also formed by milling.

1. A heat sink for dissipating heat from at least one electronic component, the heat being dissipated via at least one thermal pad located between the at least one electronic component and the heat sink,
wherein the heat sink has at least one cavity in the area where the heat sink is to contact the thermal pad.

2. The heat sink according to claim 1, wherein the heat sink is fixed to the printed circuit board carrying the electronic component capable to generate heat.

3. The heat sink according to claim 1, wherein the at least one cavity is implemented in the shape of a polygon, an ellipsoid or an oval.

4. The heat sink according to claim 1, wherein the at least one cavity is implemented in the shape of a groove.

5. The heat sink according to claim 4, wherein the groove is evenly spread over the contact surface of the heat sink.

6. The heat sink according to claim 4, wherein the groove has the shape of a meander.

7. The heat sink according to claim 1, wherein the heat sink comprises a die cast part.

8. Method of mounting a heat sink, said method comprising clamping together a heat sink according to claim 1 and a heat generating component with a thermal pad between said devices, said thermal pad filling the gap between said devices, whereby the heat sink has at least one cavity in the area where the heat sink is to contact the thermal pad.
